(19) United States
(12) Patent Application Publication
(10) Pub. No.: US 2024/0373676 A1
(43) Pub. Date: Nov. 7, 2024

(54) DISPLAY PANEL AND DISPLAY DEVICE

(71) Applicant: BOE Technology Group Co., Ltd., Beijing (CN)

(72) Inventors: Qing DAI, Beijing (CN); Li SUN, Beijing (CN); Ying CUI, Beijing (CN); Chunjing HU, Beijing (CN); Yue ZHANG, Beijing (CN)

(21) Appl. No.: 18/031,118

(22) PCT Filed: Jun. 17, 2022
(86) PCT No.: PCT/CN2022/099373

§ 371 Date: Apr. 10, 2023

(51) Int. Cl. H10K 59/122

(52) U.S. Cl. CPC H10K 59/122

(57) ABSTRACT

Provided is a display panel, including: a substrate; a pixel definition layer having at least one strip-shaped first opening therein, wherein the first opening includes an expansion region and a contraction region that are alternately arranged along a first direction, and a size of the expansion region in a second direction is larger than a size of the expansion region in the second direction; a plurality of first partition walls, disposed in the first opening, wherein each of the first partition walls extends along the second direction, and two ends of the first partition wall are respectively in contact with two side walls of the first opening to partition the first opening into a plurality of pixel openings; and a plurality of light-emitting portions, respectively disposed in the plurality of pixel openings; wherein a height of the first partition wall is less than a height of the pixel definition layer.

### CROSS-REFERENCE TO RELATED APPLICATION

The present disclosure is a U.S. national stage of international application No. PCT/CN2022/099373, filed on Jun. 17, 2022, the content of which is herein incorporated by reference in its entirety.

### TECHNICAL FIELD

The present disclosure relates to the field of display technologies, and in particular, relates to a display panel and a display device.

### BACKGROUND OF THE INVENTION

Organic light-emitting diode (OLED) display devices, due to the advantages of self-illumination, fast response, wide viewing angle, high luminance, sharp color, and thinness and lightness, are widely used in the display industry relative to liquid crystal display devices.

### SUMMARY OF THE INVENTION

Embodiments of the present disclosure provide a display panel and a display device. The technical solutions are as follows.

According to some embodiments of the present disclosure, a display panel is provided. The display panel includes:
a substrate;
a pixel definition layer, disposed on the substrate and having at least one strip-shaped first opening therein, wherein the first opening includes an expansion region and a contraction region that are alternately arranged along a first direction, and a size of the expansion region in a second direction is larger than a size of the expansion region in the second direction, the second direction being intersected with the first direction;
a plurality of first partition walls, disposed in the first opening, wherein each of the first partition walls extends along the second direction, and two ends of the first partition wall are respectively in contact with two side walls of the first opening to partition the first opening into a plurality of pixel openings; and
a plurality of light-emitting portions, respectively disposed in the plurality of pixel openings;
wherein a height of the first partition wall in a direction perpendicular to the substrate is less than a height of the pixel definition layer in the direction perpendicular to the substrate.

In some embodiments, the first opening includes a first edge extending along the first direction, wherein the first edge includes a plurality of recessed edges recessed towards an interior of the first opening, an orthographic projection of the recessed edge on the substrate being arc-shaped.

In some embodiments, the display panel further includes a plurality of second light-emitting portions, and the pixel definition layer further includes a plurality of second openings; wherein

the plurality of second light-emitting portions are respectively disposed in the plurality of second openings; and an orthographic projection of the second opening on the substrate is circular, the first opening and the second opening are alternately arranged along the second direction, in the second direction, and at least one of the plurality of second openings is disposed between adjacent two of the contraction regions.

In some embodiments, the plurality of second openings are arranged along the first direction, the plurality of recessed edges of the first edge are successively connected along the first direction, and a junction of adjacent two of the recessed edges is disposed between two of the second openings adjacent in the first direction.

In some embodiments, the display panel further includes a filling portion, wherein the filling portion is disposed at the junction of the adjacent two of the recessed edges, an orthographic projection of the filling portion on the substrate is within an orthographic projection of the first opening on the substrate, and a height of the filling portion in the direction perpendicular to the substrate is less than the height of the pixel definition layer in the direction perpendicular to the substrate.

In some embodiments, an orthographic projection of at least one of the plurality of first partition walls on the substrate is within an orthographic projection of the contraction region on the substrate, and the two ends of the first partition wall are respectively in contact with two side walls of the contraction region.

In some embodiments, the display panel further includes a plurality of second partition walls, and the pixel definition layer further includes a plurality of communication grooves; wherein
the communication groove extends along the second direction, the communication groove is disposed between two of the second openings adjacent in the first direction, and two ends of the communication groove are respectively communicated with adjacent two of the first openings; and
the plurality of second partition walls are respectively disposed in the plurality of communication grooves, wherein the second partition wall extends along the first direction, two ends of the second partition wall are respectively in contact with two side walls of the communication groove, and a height of the second partition wall in the direction perpendicular to the substrate is less than the height of the pixel definition layer in the direction perpendicular to the substrate.

In some embodiments, the pixel definition layer includes a plurality of first openings, wherein the plurality of first openings are successively arranged along the second direction, and expansion regions and contraction regions of the plurality of first openings are alternately arranged along the second direction.

In some embodiments, an orthographic projection of at least one of the plurality of first partition walls on the substrate is within an orthographic projection of the expansion region on the substrate, and the two ends of the first partition wall are respectively in contact with two side walls of the expansion region.

In some embodiments, an area of the orthographic projection of the second opening on the substrate is less than an area of an orthographic projection of the pixel opening on the substrate.

In some embodiments, the display panel further includes a green light-emitting portion, a blue light-emitting portion, and a red light-emitting portion; wherein
the green light-emitting portion is configured to emit green light, the blue light-emitting portion is configured to emit blue light, and the red light-emitting portion is configured to emit red light; and the green light-emitting portion is disposed in the pixel opening, and the blue light-emitting portion and the red light-emitting portion are disposed in the second opening.

In some embodiments, the height of the first partition wall in the direction perpendicular to the substrate ranges from 1 μm to 2.5 μm; and

the height of the pixel definition layer in the direction perpendicular to the substrate ranges from 0.3 μm to 0.8 μm.

According to some embodiments of the present disclosure, a display device is provided. The display device includes: a power supply assembly and a display panel as described, wherein the power supply assembly is configured to supply power to the display panel.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a display panel;

FIG. 2 is a curve diagram showing a comparison between a theoretical size and an actual size of a light-emitting portion illustrated in FIG. 1;

FIG. 3 is a schematic structural diagram of a display panel according to some embodiments of the present disclosure;

FIG. 4 is a schematic sectional diagram of the display panel illustrated in FIG. 3 along an A1-A2 line;

FIG. 5 is a schematic sectional diagram of the display panel illustrated in FIG. 4 along a B1-B2 line;

FIG. 6 is a schematic structural diagram of another display panel according to some embodiments of the present disclosure;

FIG. 7 is a schematic structural diagram of still another display panel according to some embodiments of the present disclosure;

FIG. 8 is a schematic structural diagram of yet still another display panel according to some embodiments of the present disclosure;

FIG. 9 is a schematic structural diagram of yet still another display panel according to some embodiments of the present disclosure;

FIG. 10 is a schematic structural diagram of yet still another display panel according to some embodiments of the present disclosure;

FIG. 11 is a schematic structural diagram of yet still another display panel according to some embodiments of the present disclosure; and

FIG. 12 is a schematic structural diagram of yet still another display panel according to some embodiments of the present disclosure.

The definite embodiments of the present disclosure illustrated by the above accompanying drawings are described in further detail hereinafter. These accompanying drawings and textual descriptions are not intended to limit the scope of the concept of the present disclosure in any form, but rather to illustrate the concepts of the present disclosure for those skilled in the art by reference to particular embodiments.

### DETAILED DESCRIPTION

The present disclosure is described in further detail with reference to the accompanying drawings, to clearly present the objects, technical solutions, and advantages of the present disclosure.

A display panel includes a substrate, a pixel definition layer (PDL), and a light-emitting layer. The light-emitting layer includes a plurality of light-emitting portions, and the pixel definition layer includes a plurality of openings defining a plurality of pixel openings arranged in arrays. The light-emitting portion is disposed in the pixel opening.

However, uniformity of thickness of the film layers of the light-emitting portions in the display panel is poor.

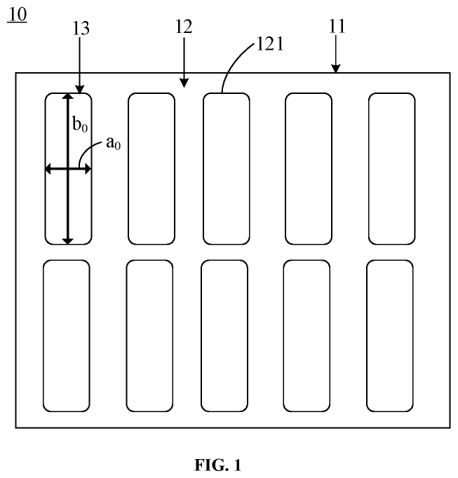

FIG. 1 is a schematic structural diagram of a display panel. Referring to FIG. 1, the display panel 10 includes a substrate 11, a pixel definition layer (PDL) 12, and a plurality of light-emitting portions 13. A plurality of pixel openings 121 are defined in the pixel definition layer 12, and the plurality of light-emitting portions 13 are disposed in the plurality of pixel openings 121. The substrate 11 includes a pixel drive circuit configured to drive the light-emitting portion to emit light.

During manufacture of the display panel 10, the light-emitting portion 13 is typically formed by a solution process. During a wet film-forming process, the pixel opening 121 is first filled with a solution (the solution is a liquid luminescent material, including a solute and a solvent) by the solution process, and then the solvent in the solution is removed by a reduced-pressure drying process, such that the solute in the pixel opening 121 forms the light-emitting portions 13. The process of filling the solution includes an inkjet printing technique, wherein a printhead of an inkjet printing device includes a plurality of nozzles to simultaneously form a plurality of light-emitting portions 13 of the same color. However, during the manufacture, the amount of ink in the plurality of nozzles fails to be kept exactly constant, such that uniformity of thickness of film layers of the plurality of light-emitting portions 13 is poor, and thus uniformity of luminescence of the plurality of light-emitting portions 13 is also poor.

Moreover, the process of drying the solution is prone to the poor uniformity of the formed light-emitting portions 13, and thus the display effect of the display panel 10 is affected. Specifically, degradation of the display effect is exhibited in the following two aspects.

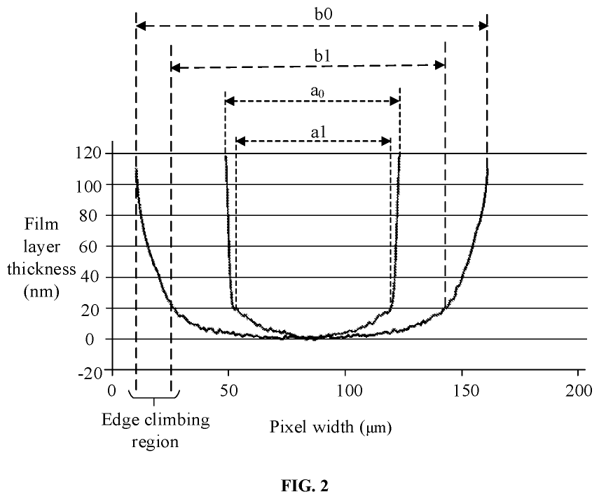

In one aspect, the volume of the solution shrinks as the evaporation of the solvent, but a position of an interface where the solution initially is in contact with a side wall of the pixel opening remains unchanged due to a pinning effect between the solution and the side wall of the pixel opening 121. A climbing phenomenon occurs to an edge of the light-emitting portion 13 formed upon drying because of the pinning effect. Exemplarily, as illustrated in FIG. 2, FIG. 2 is a curve diagram showing a comparison between a theoretical size and an actual size of a light-emitting portion illustrated in FIG. 1. FIG. 2 illustrates an effect diagram of an edge climbing phenomenon of the light-emitting portion 13 formed by the solution process. Referring to FIG. 1 simultaneously, an orthographic projection of the light-emitting portion 13 on the substrate 21 is rectangular, and a theoretical width of a light-emitting region of the light-emitting portion 13 is a0 and a theoretical length is b0. However, in the actually formed light-emitting portion 13, an actual width of the light-emitting region (description is given in FIG. 2 using a width corresponding to a film layer having a thickness of 20 nm as an example, and in the case that the thickness of the film layer in the light-emitting portion is great, the portion having a great thickness of the film layer fails to be used for emitting light) is a1, and an actual length is b1. Theoretically, the smaller the difference between the actual width a1 and the theoretical width a0 of the light-emitting portion 13, the smaller the difference between the actual length b1 and the theoretical length b0, that is, the thicknesses of the film layers of different regions of the light-emitting portion 13 in the pixel opening 121 are equal, and the greater the light-emitting area of the light-emitting portion 13. However, in an actual manufacture process, the light-emitting area of the light-emitting portion 13 is small due to the climbing phenomenon.

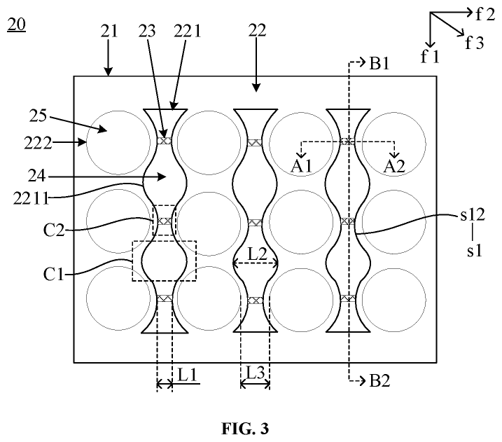

In another aspect, due to a large difference between the length and width of the pixel opening 121, during the reduced-pressure drying process, micro forces on the solution in a length direction of the pixel opening 121 are different from micro forces on the solution in a width direction of the pixel opening 121, such that the film layers of the light-emitting portions 13 formed upon drying are unevenly distributed in the pixel openings 121. Exemplarily, in FIG. 3, a difference between a value of a1/a0 and a value of b1/b0 under the same reduced-pressure drying process is great. That is, under the same reduced-pressure drying process, the light-emitting portion 13 achieves good flatness in the width direction whereas poor flatness in the length direction. Therefore, the flatness of the luminescent material is poor, and thus the uniformity of luminance of the light-emitting portion 13 is poor.

The embodiments of the present disclosure provide a display panel and a display device, which solve the above problem in some practices.

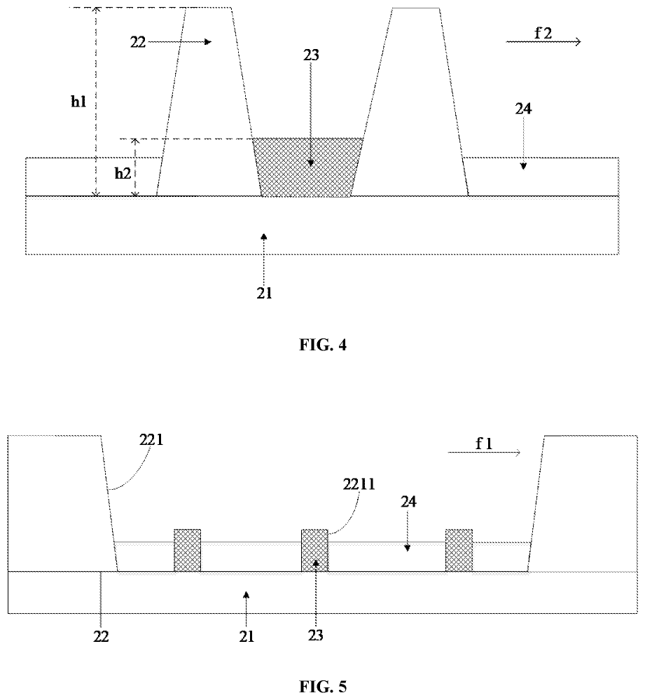

FIG. 3 is a schematic structural diagram of a display panel according to some embodiments of the present disclosure. FIG. 4 is a schematic sectional diagram of the display panel illustrated in FIG. 3 along an A1-A2 line. FIG. 5 is a schematic sectional diagram of the display panel illustrated in FIG. 4 along a B1-B2 line. Referring to FIG. 3 and FIG. 4, the display panel 20 includes a substrate 21, a pixel definition layer 22, a plurality of first partition walls 23, and a plurality of first light-emitting portions 24.

The substrate 21 includes a pixel drive circuit configured to drive the first light-emitting portion 24 to emit light. The pixel definition layer 22 is disposed on the substrate 21, and the pixel definition layer 22 has at least one strip-shaped first opening 221 therein. The first opening 221 includes an expansion region C1 and a contraction region C2 that are alternately arranged along a first direction f1. A size of the expansion region C1 in a second direction f2 is larger than a size of the contraction region C2 in the second direction f2, wherein the second direction f2 is intersected with the first direction f1. That is, the size of the strip-shaped first opening 221 in the second direction f2 is not a constant value, and the first opening 221 has different sizes at different positions in the first direction f1.

The plurality of first partition walls 23 are disposed in the first opening 221. Each of the first partition walls 23 extends along the second direction f2, and two ends of the first partition wall 23 are respectively in contact with two side walls of the first opening 221 to partition the first opening 221 into a plurality of pixel openings 2211. The plurality of first partition walls 23 are configured to define the plurality of pixel openings 2211 in the first opening 221, and the plurality of pixel openings 2211 in the first opening 221 are arranged along the first direction f1.

A height of the first partition wall 23 in a direction perpendicular to the substrate 21 is less than a height of the pixel definition layer 22 in the direction perpendicular to the substrate 21. That is, a distance between a side, distal from the substrate 21, of the pixel definition layer 22 and the substrate 21 is greater than a distance between a side, distal from the substrate 21, of the first partition wall 23 and the substrate 21.

The plurality of first light-emitting portions 24 are respectively disposed in the plurality of pixel openings 2211. That is, the plurality of first light-emitting portions 24 are in one-to-one correspondence to the plurality of pixel openings 2211. The plurality of first light-emitting portions 24 are disposed in the same first opening 221, and the plurality of first light-emitting portions 24 in the first opening 221 are arranged along the first direction f1.

The plurality of first light-emitting portions 24 disposed in the same first opening 221 may be made of the same luminescent material. In the process of forming the first light-emitting portion 24 by filling the first opening 221 with a liquid luminescent material by a solution process, the plurality of pixel openings 2211 in the first opening 221 are communicated with each other, such that the liquid luminescent material flows between the plurality of pixel openings 2211 in the first opening 221, and thus the luminescent materials with approximate thicknesses are formed within the plurality of pixel openings 2211 in the first opening 221. In this way, the uniformity of thickness of film layers of the plurality of first light-emitting portions 24 in the first opening 221 is improved, such that the uniformity of luminescence of the plurality of first light-emitting portions 24 is improved. The process of filling the solution in the above solution process includes an inkjet printing technique.

In summary, some embodiments of the present disclosure provide a display panel. The display panel includes the substrate, the pixel definition layer, the plurality of first partition walls, and the plurality of first light-emitting portions. The plurality of first partition walls are disposed in the first opening of the pixel definition layer and partition the first opening into the plurality of pixel openings. The height of the pixel definition layer is greater than the height of the first partition wall. In this way, in the process of forming the first light-emitting portion by filling the first opening with the liquid luminescent material, the liquid luminescent material flows between the plurality of pixel openings within the first opening, such that the difference between the thicknesses of the luminescent materials in the plurality of pixel openings is reduced. Therefore, the uniformity of thickness of the film layers of the plurality of first light-emitting portions is improved, and thus the quality of the display panel is improved.

Optionally, as illustrated in FIG. 3, the first opening 221 includes a first edge s1 extending along the first direction f1. An orthographic projection of the first edge s1 on the substrate 21 is wavy. The first edge s1 includes a plurality of recessed edges s12 recessed towards an interior of the first opening 221. An orthographic projection of the recessed edge s12 on the substrate 21 is arc-shaped.

The first opening 221 includes two first edges s1. The two first edges s1 are symmetrical in the second direction f2 about an axis of symmetry, which runs through a center, in the second direction f2, of the first opening 221 and is parallel to the first direction f1. The first direction f1 is perpendicular to the second direction f2. Directions of opening of two recessed edges s12 at the same position, in the first direction f1, of the first opening 221 are opposite.

The orthogonal projection of the recessed edge s12 on the substrate 21 is arc-shaped, such that at least part of edges of the pixel openings 2211 are arc-shaped, which facilitates wetting and spreading of the liquid luminescent material in the pixel opening 2211 during the inkjet printing process, and facilitates the flow of the liquid luminescent material between the plurality of pixel openings 2211. In addition, compared with rectangular pixel openings in some practices, the pixel opening 2211 with arc-shaped edges in the present disclosure has smaller side lengths, which reduces the impact of the edge climbing phenomenon. In this way, the luminescent materials between the plurality of pixel openings 2211 complement each other when flowing, such that the thicknesses of the film layers of the luminescent materials are uniform, and thus the uniformity of thickness of the film layers of the plurality of first light-emitting portions 24 in the first opening 221 is improved, and the uniformity of luminescence of the plurality of first light-emitting portions 24 is further improved.

Optionally, as illustrated in FIG. 4, the height h1 of the pixel definition layer 22 in the direction perpendicular to the substrate 21 ranges from 1 μm to 2.5 μm; and the height h2 of the first partition wall 23 in the direction perpendicular to the substrate 21 ranges from 0.3 μm to 0.8 μm.

The pixel definition layer 22 includes a two-layer stacked structure, wherein a bottom portion proximal to the substrate 21 has a hydrophobic property and a top portion distal from the substrate 21 has a hydrophilic property. The first partition wall 23 has a hydrophobic property. In this way, the bottom portion of the pixel definition layer 22 and the first partition wall 23 that have the hydrophobic property facilitate the flow of the liquid luminescent material in the first opening 221 and wetting and spreading of the liquid luminescent material in the pixel opening 2211 of the first opening 221. The top portion of the pixel definition layer 22 having the hydrophobic property prevents the liquid luminescent material from flowing out of the first opening 221.

It should be noted that during manufacture of the display panel 20, the height of the liquid luminescent material in the direction perpendicular to the substrate 21 is greater than the height of the first partition wall 23, and the thickness of the luminescent material is less than the height of the first partition wall 23 in the case that the liquid luminescent material is dried by the reduced-pressure drying process. That is, the first partition wall 23 is capable of preventing, by partitioning two of the first light-emitting portions 24 adjacent in the second direction f2, the adjacent two first light-emitting portions 24 from being connected in series.

Optionally, as illustrated in FIG. 3, the display panel 20 further includes a plurality of second light-emitting portions 25, and the pixel definition layer 22 further includes a plurality of second openings 222. The plurality of second light-emitting portions 25 are respectively disposed in the plurality of second openings 222. That is, the plurality of second light-emitting portions 25 are in one-to-one correspondence to the plurality of second openings 222.

An orthographic projection of the second opening 222 on the substrate 21 is circular. The first openings 221 and the second openings 222 are alternately arranged along the second direction f2, and at least one of the plurality of second openings 222 is disposed between two of the contraction regions C2 adjacent in the second direction f2. An orthographic projection of a line connecting centers of two of the second openings 222 adjacent in the second direction f2 on the substrate 21 is overlapped with an orthographic projection of the contraction region C2 between the adjacent two second openings 222 on the substrate 21.

Compared with the rectangular pixel openings in some practices, the second opening 222 in the embodiments of the present disclosure is circular, which facilitates wetting and spreading of the liquid luminescent in the second opening 222 during the inkjet printing process. Moreover, the circular second opening 222 has smaller side lengths, which reduces the impact caused by the edge climbing phenomenon.

In addition, during the reduced-pressure drying process, the solution is subjected to the same micro forces in all directions of the circular second opening 222, such that a distribution of the film layers of the second light-emitting portions 25 formed upon drying in the pixel openings 2211 is uniform.

As illustrated in FIG. 3, the plurality of second openings 222 are arranged along a third direction f3, and the expansion region C1 of the first opening 221 is disposed between two of the second openings 222 adjacent in the third direction f3, wherein the third direction f2 is intersected with the first direction f1 and the second direction f2. Exemplarily, an included angle between the third direction f3 and the first direction is 45 degrees. In the case that a distance between two of the second openings 222 adjacent in the third direction f3 is large, the expansion region C1 of the first opening 221 is arranged in a region between the second openings 222 adjacent along the third direction f3; and in the case that a distance between two of the second openings 222 in the second direction f2 is small, the contraction region C2 of the first opening 221 is arranged in a region between the second openings 222 adjacent along the second direction f2. In this way, the layout space in the display panel 20 is more reasonably utilized, such that space utilization of the display panel 20 is improved, and thus more first light-emitting portions 24 and more second light-emitting portions 25 are arranged in a unit area of the display panel 20.

Referring to FIG. 3, the size L1 of the contraction region C2 of the first opening 221 in the second direction f2 is larger than or equal to 5 μm, and the size L2 of the expansion region C1 of the first opening 221 in the second direction f2 is larger than or equal to 10 μm. The shortest distance L3 between two of the second openings 222 adjacent in the second direction f2 is greater than or equal to 15 μm.

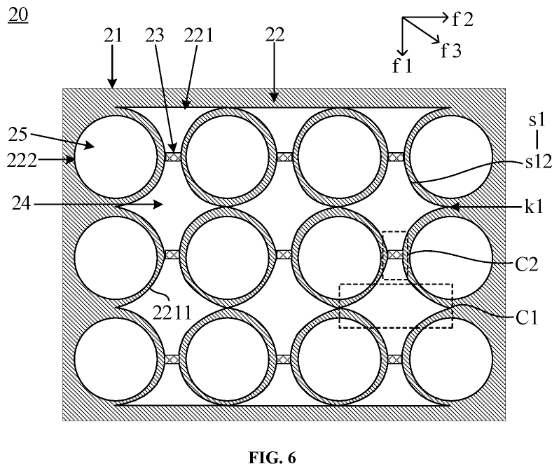

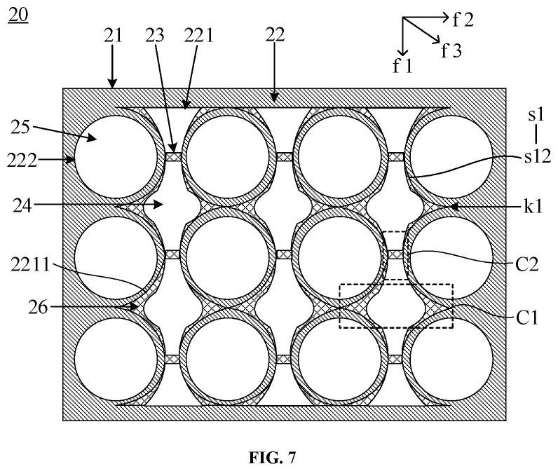

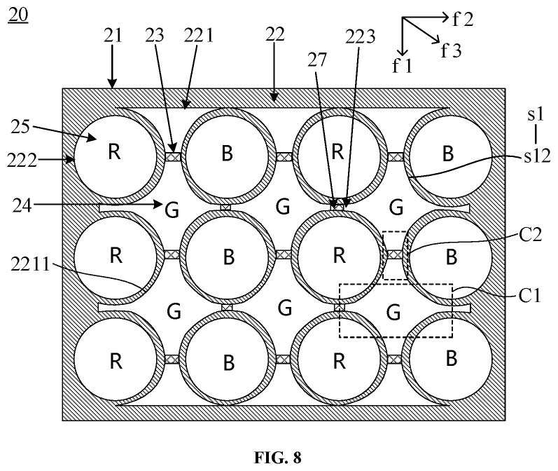

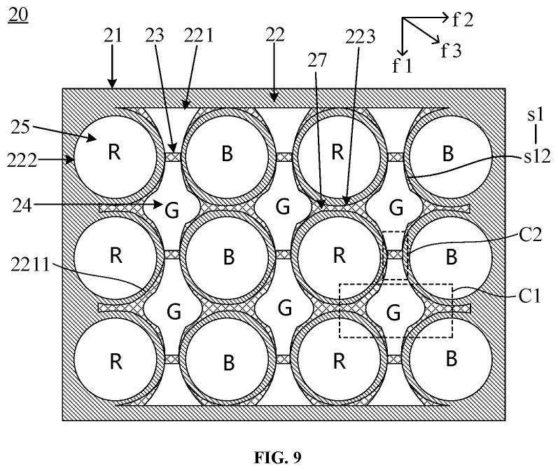

Optionally, FIG. 6 is a schematic structural diagram of another display panel according to some embodiments of the present disclosure. It should be noted that for clearer illustration of the shape of the pixel definition layer 22, the pixel definition layer 22 is filled in FIG. 6, the pixel definition layer 22 illustrated in FIG. 6 and the pixel definition layer 22 illustrated in FIG. 3 are likewise constructed in all aspects other than the shape, and the pixel definition layers in FIG. 7, FIG. 8, and FIG. 9 are filled for the same reason. Referring to FIG. 6, the plurality of second openings 222 are arranged along the first direction f1, and the plurality of recessed edges s12 in the first edge s1 of the first opening 221 are successively connected along the first direction f1. A junction kl of adjacent two of the recessed edges s12 is disposed between two of the second openings 222 adjacent in the first direction f1. The curvature of the recessed edge s12 and the curvature of the second opening 222 are the same, and shortest distances between a plurality of positions on the recessed edge s12 and the second opening 222 are the same.

In this way, a size of the pixel definition layer 22 between the first opening 221 and the second opening 222 in a direction parallel to the substrate 21 is small, and a size of the expansion region C1 of the first opening 221 in the direction parallel to the substrate 21 is large, such that an aperture rate of the first opening 221 is improved.

In some optional embodiments, at least some of the junctions kl of two of the first openings 221 adjacent in the second direction f2 are in contact, such that two of the recessed edges s12 adjacent in the second direction f2 enclose the second opening 222 disposed between the two recessed edges s12.

FIG. 7 is a schematic structural diagram of still another display panel according to some embodiments of the present disclosure. Optionally, as illustrated in FIG. 7, the display panel further includes a filling portion 26. The filling portion 26 is disposed at the junction kl of adjacent two of the recessed edges s12, and an orthographic projection of the filling portion 26 on the substrate 21 is within an orthographic projection of the first opening 221 on the substrate 21. A height of the filling portion 26 in the direction perpendicular to the substrate 21 is less than the height of the pixel definition layer 22 in the direction perpendicular to the substrate 21. The filling portion 26 and the first partition wall 23 are the same layer structure and are made of the same material.

A side, distal from a center of the expansion region C1 of the first opening 221, of the filling portion 26 is in contact with a side wall of the expansion region C1. The filling portion 26 is configured to avoid an accumulation of the luminescent material, which is in the first opening 221, at the junction kl of two of the recessed edges s12, such that the thicknesses of the film layers of the luminescent material in the first opening 221 is more uniform.

FIG. 8 is a schematic structural diagram of yet still another display panel according to some embodiments of the present disclosure. Optionally, as illustrated in FIG. 8, the display panel 20 further includes a plurality of second partition walls 27, and the pixel definition layer 22 includes a plurality of communication grooves 223. Each of the communication grooves 223 extends along the second direction f2, and the communication groove 223 is disposed between two of the second openings 222 adjacent in the first direction f1. Two ends of the connection slot 223 are respectively communicated with adjacent two first openings 221, such that the adjacent two first openings 221 are communicated with each other in the second direction f2 by the connection slot 223, and thus the first openings 221 are a netlike structure. That is, the pixel openings 2211 in the plurality of first openings 221 are communicated in both the first direction f1 and the second direction f2. In this way, the uniformity of thickness of the film layers of the plurality of first light-emitting portions 24 in the first opening 221 is further improved, and thus the uniformity of luminescence of the plurality of first light-emitting portions 24 is further improved.

The plurality of second partition walls 27 are respectively disposed in the plurality of communication grooves 223, and each of the second partition walls 27 extends along the first direction f1. Two ends of the second partition wall 27 are respectively in contact with two side walls of the communication groove 223. A height of the second partition wall 27 in the direction perpendicular to the substrate 21 is less than the height of the pixel definition layer 22 in the direction perpendicular to the substrate 21. The second partition wall 27 and the first partition wall 23 are the same layer structure and are made of the same material. The second partition wall 27 prevents, by partitioning two of the first light-emitting portions 24 adjacent in the second direction f2, the adjacent two first light-emitting portions 24 from being connected in series.

FIG. 9 is a schematic structural diagram of yet still another display panel according to some embodiments of the present disclosure. Optionally, as illustrated in FIG. 9, a shortest distance between two of the second openings 222 adjacent in the second direction f2 is greater than a shortest distance between two of the second openings 222 adjacent in the first direction f1. A size of the second partition wall 27 in the second direction f2 is large and is larger than a size of the communication groove 223 in the second direction f2, and the second partition wall 27 is disposed in an edge region of the expansion region C1 and the contraction region C2 of the first opening 221. In this way, the shape of the first light-emitting portion 24 is defined by the second partition wall 27, and an accumulation of a large amount of the luminescent material in the communication groove 223 of a smaller size is avoided.

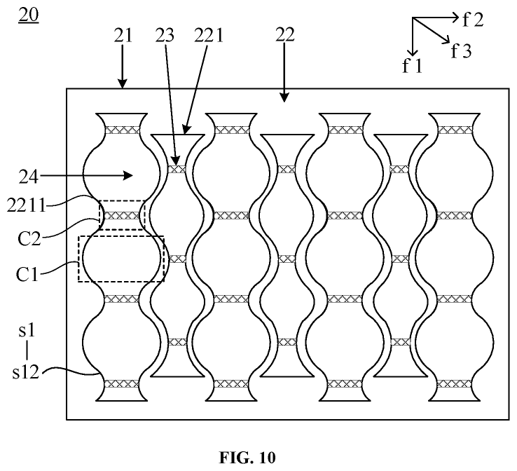

FIG. 10 is a schematic structural diagram of yet still another display panel according to some embodiments of the present disclosure. Optionally, as illustrated in FIG. 10, the pixel definition layer 22 includes a plurality of first openings 221, and the plurality of first openings 221 are successively arranged along the second direction f2. The expansion regions C1 and the contraction regions C2 of the plurality of first openings 221 are alternately arranged along the second direction f2. The plurality of expansion regions C1 of the plurality of first openings 221 are arranged along the third direction f3. In this way, the plurality of first openings 221 are proximal to each other, such that more first light-emitting portions 24 are arranged in a unit area of the display panel 20.

As illustrated in FIG. 10, sizes of two of the first openings 221 adjacent in the second direction f2 are different. A plurality of types of first light-emitting portions 24 are arranged in the pixel openings 2211 of the adjacent two first openings 221, and the plurality of types of first light-emitting portions 24 emit light of multiple colors. Different types of first light-emitting portions 24 are arranged in the first openings 221 of different sizes by flexibly arranging the sizes of the first openings 21.

Optionally, as illustrated in FIG. 10, an orthographic projection of at least one of the plurality of first partition walls 23 on the substrate 21 is within the orthographic projection of the contraction region C2 on the substrate 21, and the two ends of the first partition wall 23 are respectively in contact with two side walls of the contraction region C2. The first light-emitting portion 24 is disposed in the expansion region C1 of the first opening 221. In this way, a size of the first partition wall 23 is small and a size of the first light-emitting portion 24 in the first opening 221 is large, such that the aperture ratio of the display panel 21 is increased.

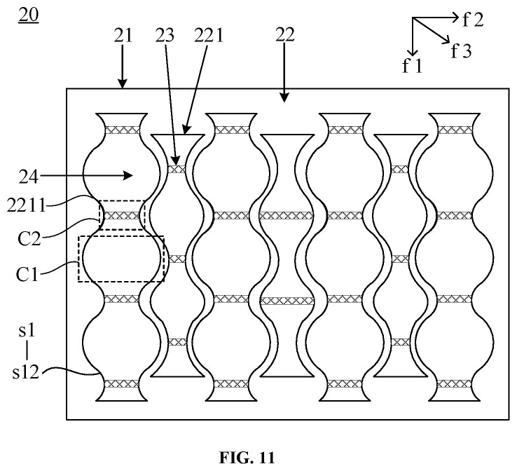

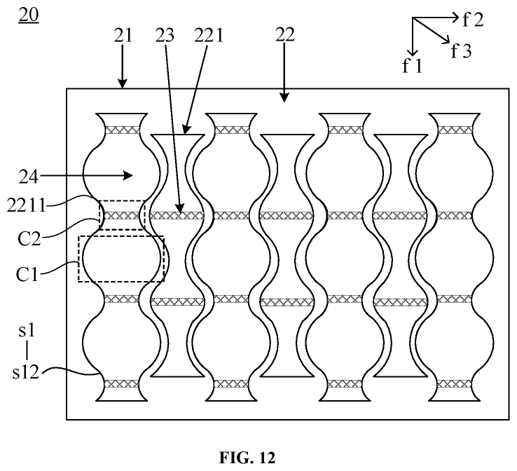

FIG. 11 is a schematic structural diagram of yet still another display panel according to some embodiments of the present disclosure, and FIG. 12 is a schematic structural diagram of yet still another display panel according to some embodiments of the present disclosure. Optionally, as illustrated in FIG. 11 and FIG. 12, the orthographic projection of at least one of the plurality of first partition walls 23 on the substrate 21 is within an orthographic projection of the expansion region C1 on the substrate 21, and the two ends of the first partition wall 23 are respectively in contact with two side walls of the expansion region C1. The larger the size of the first partition wall 23, the smaller the size of the first light-emitting portion 24 in the first opening 221. Therefore, the sizes of the different types of first light-emitting portions 24 in the plurality of first openings 221 are regulated by regulating a position where the first partition wall 23 is in the first opening 221.

Optionally, as illustrated in FIG. 3, an area of the orthographic projection of the second opening 222 on the substrate 21 is greater than an area of an orthographic projection of the pixel opening 2211 on the substrate 21. The plurality of pixel openings 2211 are communicated with each other in the first direction f1 due to the small area of the pixel opening 2211, such that the plurality of pixel openings 2211 achieve a large ink-jet printing window during the ink-jet printing process, and thus the difficulty of the ink-jet printing process is reduced, and the difficulty in manufacturing the display panel 20 is further reduced.

Optionally, as illustrated in FIG. 9, the display panel includes a green light-emitting portion G, a blue light-emitting portion B, and a red light-emitting portion R. The green light-emitting portion G is configured to emit green light, the blue light-emitting portion B is configured to emit blue light, and the red light-emitting portion R is configured to emit red light. The green light-emitting portion G is within the pixel opening 2211, and the blue light-emitting portion B and the red light-emitting portion are respectively within the second opening 222.

In summary, some embodiments of the present disclosure provide a display panel. The display panel includes: the substrate, the pixel definition layer, the plurality of first partition walls, and the plurality of first light-emitting portions. The plurality of first partition walls are disposed in the first opening of the pixel definition layer and partition the first opening into the plurality of pixel openings. The height of the pixel definition layer is greater than the height of the first partition wall. In this way, during the process of forming the first light-emitting portion by filling the first opening with the liquid luminescent material, the liquid luminescent material flows between the plurality of pixel openings within the first opening, such that the difference between the thicknesses of the luminescent materials in the plurality of pixel openings is reduced. Therefore, the uniformity of thickness of the film layers of the plurality of first light-emitting portions is improved, and thus the quality of the display panel is improved.

Some embodiments of the present disclosure further provide a display device. The display device includes a power supply assembly and a display panel. The power supply assembly is configured to supply power to the display panel. The display panel is the display panel as described above.

The display device is a smartphone, a tablet computer, a television, a display, a notebook computer, a digital photo frame, a navigator, and any other product with a display function.

It should be noted that in the accompanying drawings, sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

In the present disclosure, the terms “first” and “second” are only used for descriptive purposes, and cannot be understood as indicating or implying relative importance. The term “a plurality of” refers to two or more, unless expressly defined otherwise.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display panel, comprising:
a substrate;
a pixel definition layer, disposed on the substrate and having at least one strip-shaped first opening therein, wherein the first opening comprises an expansion region and a contraction region that are alternately arranged along a first direction, and a size of the expansion region in a second direction is larger than a size of the expansion region in the second direction, the second direction being intersected with the first direction;
a plurality of first partition walls, disposed in the first opening, wherein each of the first partition walls extends along the second direction, and two ends of the first partition wall are respectively in contact with two side walls of the first opening to partition the first opening into a plurality of pixel openings; and
a plurality of light-emitting portions, respectively disposed in the plurality of pixel openings;
wherein a height of the first partition wall in a direction perpendicular to the substrate is less than a height of the pixel definition layer in the direction perpendicular to the substrate.

2. The display panel according to claim 1, wherein the first opening comprises a first edge extending along the first direction, wherein the first edge comprises a plurality of recessed edges recessed towards an interior of the first opening, an orthographic projection of the recessed edge on the substrate being arc-shaped.

3. The display panel according to claim 2, wherein the display panel further comprises a plurality of second light-emitting portions, and the pixel definition layer further comprises a plurality of second openings; wherein
the plurality of second light-emitting portions are respectively disposed in the plurality of second openings; and
an orthographic projection of the second opening on the substrate is circular, the first opening and the second opening are alternately arranged along the second direction, in the second direction, and at least one of the plurality of second openings is disposed between adjacent two of the contraction regions.

4. The display panel according to claim 3, wherein the plurality of second openings are arranged along the first direction, the plurality of recessed edges of the first edge are successively connected along the first direction, and a junction of adjacent two of the recessed edges is disposed between two of the second openings adjacent in the first direction.

5. The display panel according to claim 4, further comprising: a filling portion;
wherein the filling portion is disposed at the junction of the adjacent two of the recessed edges, an orthographic projection of the filling portion on the substrate is within an orthographic projection of the first opening on the substrate, and a height of the filling portion in the direction perpendicular to the substrate is less than the height of the pixel definition layer in the direction perpendicular to the substrate.

6. The display panel according to claim 1, wherein an orthographic projection of at least one of the plurality of first partition walls on the substrate is within an orthographic projection of the contraction region on the substrate, and the two ends of the first partition wall are respectively in contact with two side walls of the contraction region.

7. The display panel according to claim 3, wherein the display panel further comprises a plurality of second partition walls, and the pixel definition layer further comprises a plurality of communication grooves; wherein
the communication groove extends along the second direction, the communication groove is disposed between two of the second openings adjacent in the first direction, and two ends of the communication groove are respectively communicated with adjacent two of the first openings; and
the plurality of second partition walls are respectively disposed in the plurality of communication grooves, wherein the second partition wall extends along the first direction, two ends of the second partition wall are respectively in contact with two side walls of the communication groove, and a height of the second partition wall in the direction perpendicular to the substrate is less than the height of the pixel definition layer in the direction perpendicular to the substrate.

8. The display panel according to claim 1, wherein the pixel definition layer comprises a plurality of first openings, wherein the plurality of first openings are successively arranged along the second direction, and expansion regions and contraction regions of the plurality of first openings are alternately arranged along the second direction.

9. The display panel according to claim 8, wherein an orthographic projection of at least one of the plurality of first partition walls on the substrate is within an orthographic projection of the expansion region on the substrate, and the two ends of the first partition wall are respectively in contact with two side walls of the expansion region.

10. The display panel according to claim 3, wherein an area of the orthographic projection of the second opening on the substrate is less than an area of an orthographic projection of the pixel opening on the substrate.

11. The display panel according to claim 10, further comprising: a green light-emitting portion, a blue light-emitting portion, and a red light-emitting portion; wherein
the green light-emitting portion is configured to emit green light, the blue light-emitting portion is configured to emit blue light, and the red light-emitting portion is configured to emit red light; and
the green light-emitting portion is disposed in the pixel opening, and the blue light-emitting portion and the red light-emitting portion are disposed in the second opening.

12. The display panel according to claim 1, wherein
the height of the first partition wall in the direction perpendicular to the substrate ranges from 1 μm to 2.5 μm; and
the height of the pixel definition layer in the direction perpendicular to the substrate ranges from 0.3 μm to 0.8 μm.

13. A display device, comprising: a power supply assembly, and a display panel; wherein
the power supply assembly is configured to supply power to the display panel; and
the display panel comprises:
a substrate;
a pixel definition layer, disposed on the substrate and having at least one strip-shaped first opening therein, wherein the first opening comprises an expansion region and a contraction region that are alternately arranged along a first direction, and a size of the expansion region in a second direction is larger than a size of the expansion region in the second direction, the second direction being intersected with the first direction;
a plurality of first partition walls, disposed in the first opening, wherein each of the first partition walls extends along the second direction, and two ends of the first partition wall are respectively in contact with two side walls of the first opening to partition the first opening into a plurality of pixel openings; and
a plurality of light-emitting portions, respectively disposed in the plurality of pixel openings;
wherein a height of the first partition wall in a direction perpendicular to the substrate is less than a height of the pixel definition layer in the direction perpendicular to the substrate.

14. The display device according to claim 13, wherein the first opening comprises a first edge extending along the first direction, wherein the first edge comprises a plurality of recessed edges recessed towards an interior of the first opening, an orthographic projection of the recessed edge on the substrate being arc-shaped.

15. The display device according to claim 14, wherein the display panel further comprises a plurality of second light-emitting portions, and the pixel definition layer further comprises a plurality of second openings; wherein
the plurality of second light-emitting portions are respectively disposed in the plurality of second openings; and
an orthographic projection of the second opening on the substrate is circular, the first opening and the second opening are alternately arranged along the second direction, in the second direction, and at least one of the plurality of second openings is disposed between adjacent two of the contraction regions.

16. The display device according to claim 15, wherein the plurality of second openings are arranged along the first direction, the plurality of recessed edges of the first edge are successively connected along the first direction, and a junction of adjacent two of the recessed edges is disposed between two of the second openings adjacent in the first direction.

17. The display device according to claim 16, wherein the display panel further comprises: a filling portion;
wherein the filling portion is disposed at the junction of the adjacent two of the recessed edges, an orthographic projection of the filling portion on the substrate is within an orthographic projection of the first opening on the substrate, and a height of the filling portion in the direction perpendicular to the substrate is less than the height of the pixel definition layer in the direction perpendicular to the substrate.

18. The display device according to claim 13, wherein an orthographic projection of at least one of the plurality of first partition walls on the substrate is within an orthographic projection of the contraction region on the substrate, and the two ends of the first partition wall are respectively in contact with two side walls of the contraction region.

19. The display device according to claim 15, wherein the display panel further comprises a plurality of second partition walls, and the pixel definition layer further comprises a plurality of communication grooves; wherein
the communication groove extends along the second direction, the communication groove is disposed between two of the second openings adjacent in the first direction, and two ends of the communication groove are respectively communicated with adjacent two of the first openings; and
the plurality of second partition walls are respectively disposed in the plurality of communication grooves, wherein the second partition wall extends along the first direction, two ends of the second partition wall are respectively in contact with two side walls of the communication groove, and a height of the second partition wall in the direction perpendicular to the substrate is less than the height of the pixel definition layer in the direction perpendicular to the substrate.

20. The display device according to claim 13, wherein the pixel definition layer comprises a plurality of first openings, wherein the plurality of first openings are successively arranged along the second direction, and expansion regions and contraction regions of the plurality of first openings are alternately arranged along the second direction.
